(19) United States
(12) Patent Application Publication
(10) Pub. No.: US 2018/0157169 A1
(43) Pub. Date: Jun. 7, 2018

(54) METAL ELECTRODE FORMATION FOR OLED LIGHTING APPLICATIONS

(71) Applicant: SABIC Global Technologies B.V., Bergen op Zoom (NL)

(72) Inventor: Sang Hoon KIM, Seoul (KR)

(21) Appl. No.: 15/580,311

(22) PCT Filed: Jun. 15, 2016
(86) PCT No.: PCT/IB2016/053547

§ 371 Date: Dec. 7, 2017

Related U.S. Application Data
(60) Provisional application No. 62/175,606, filed on Jun. 15, 2015.

(51) Int. Cl. G03F 7/00; H01L 51/00; H01L 51/52; H01L 51/56

(52) U.S. Cl. CPC G03F 7/0002; H01L 51/56; H01L 51/5209; H01L 51/0021

(57) ABSTRACT

The instant disclosure concerns methods of producing a transparent electrode film comprising (i) contacting a film comprising a substrate having a polymer coating with a mold which encircles a roller, and wherein the contacting produces a plurality of holes within the polymer coating; the holes occurring at a frequency period of about 100 nm to about 100 μm; (ii) curing the polymer coating to produce a cured polymer coating; and (ii) depositing a metal layer on the cured polymer coating.

### RELATED APPLICATIONS

This application claims benefit of U.S. Patent Application No. 62/175,606 filed on Jun. 15, 2015, the disclosure of which is incorporated herein in its entirety.

### TECHNICAL FIELD

The disclosure concerns metal electrodes useful in organic light emitting diode (OLED) applications and the formation of such electrodes.

### BACKGROUND

A transparent conductive film (TCF) is required in small and medium size electronics such as tablets, notebooks, monitors, and smart phones. In addition, large area applications such as OLED (organic light emitting diode) lighting, OPV (organic photovoltaics) and DSSCs (dye-sensitized solar cells) need transparent conductive films. As the active area of application increases, TCF with more uniform and lower sheet resistance is required. Moreover, high transmittance and smooth surface roughness is necessary when such films are integrated into a device. The conventional transparent electrode comprises ITO (indium tin oxide) and continues to be widely used in many applications. However, ITO has some drawbacks such as brittleness and relatively higher sheet resistance, which is not easily adaptable for flexible and large area applications.

There are several known methods to fabricate transparent conductive films. A first method uses silver nanowires or nanoparticles coatings where haze can increase as sheet resistance is reduced. A second method for fabricating conductive TCFs is direct printing, including screen, flexographic and gravure printing. With these methods, an acceptable line width is difficult to attain below about 20-25 micrometers (μm), which is visible to the naked eye. A third method is embossing which can result in a metal mesh structure. The line width can be reduced to a few micrometers, making it invisible to the naked eye. While this method might seem to be a promising solution, it is difficult to make the needed nano-scale pattern. If a nano-scale pattern can be made, then high transmittance and low sheet resistance will be attained. A final method is photolithography (followed by etching). This can also be used to make metal mesh structures that are invisible to the naked eye. However, this process is very complicated and fabrication cost is high.

Unlike a wire grid polarization film where polarization is only possible in one direction due to the ridge pattern of the film, TCFs have a hole pattern or cross line pattern necessary for the electrode applications described herein.

It is desirable to discover other films and methods to replace those associated with ITO films and overcome the deficiencies of other known fabrication methods.

### SUMMARY

The instant disclosure concerns producing a transparent electrode film comprising (i) contacting a polymer coating, which resides on a substrate, with a mold, wherein the mold encircles a roller, and wherein the contacting produces a plurality of holes within the polymer coating; the holes occurring at a frequency period of 100 nm to about 100 μm; (ii) curing the polymer coating to produce a cured polymer coating; and (iii) depositing a metal layer on the cured polymer coating.

### BRIEF DESCRIPTION OF THE DRAWINGS

FIG. 1 presents a schematic of a laser interference lithography setup.

FIG. 2 shows a schematic of a roller which is encircled by a mold.

FIG. 3 presents a schematic of an overall process for the fabrication of a transparent electrode film.

FIG. 4 is a flow chart for a process such as the one presented in FIG. 3.

FIG. 5 is a field emission scanning electron microscopy (FESEM) image of a polymer mold.

FIG. 6 is a FESEM image of a patterned polymer coating on a substrate produced by a mold of the instant invention.

FIG. 7 is a FESEM image of a patterned polymer coating on a substrate where a conductive layer was obliquely deposited onto the polymer coating.

FIG. 8 shows exemplary mold shapes and final patterning after the metal layer is applied.

FIG. 9 shows a cross-sectional schematic of a transparent electrode for OLED lighting.

FIG. 10 presents a top view schematic of a transparent electrode for OLED lighting.

### DETAILED DESCRIPTION OF ILLUSTRATIVE EMBODIMENTS

In this disclosure, an innovative fabrication method for a transparent conductive film is described. A nano-sized mold, such as a mold produced by laser interference lithography, is used in the method and encircles a roller. The mold and roller can be used for producing holes in a polymer coating which resides on a substrate. Nano patterns may be obliquely deposited, for example, with a metal evaporation method, which avoids conventional steps of etching, masking, and an aligning process. Accordingly, the transparent conductive film typically comprises a substrate, a polymer coating, and a metal layer.

### Mold Production

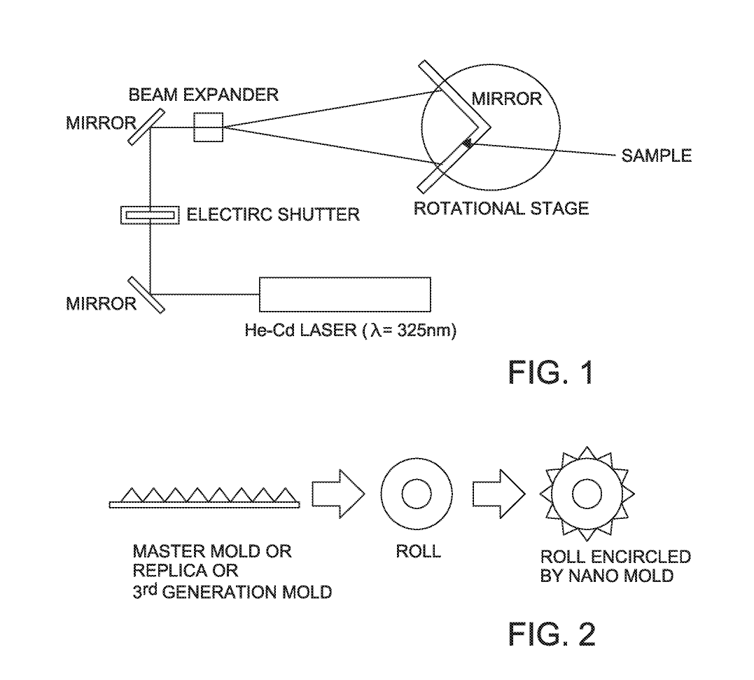

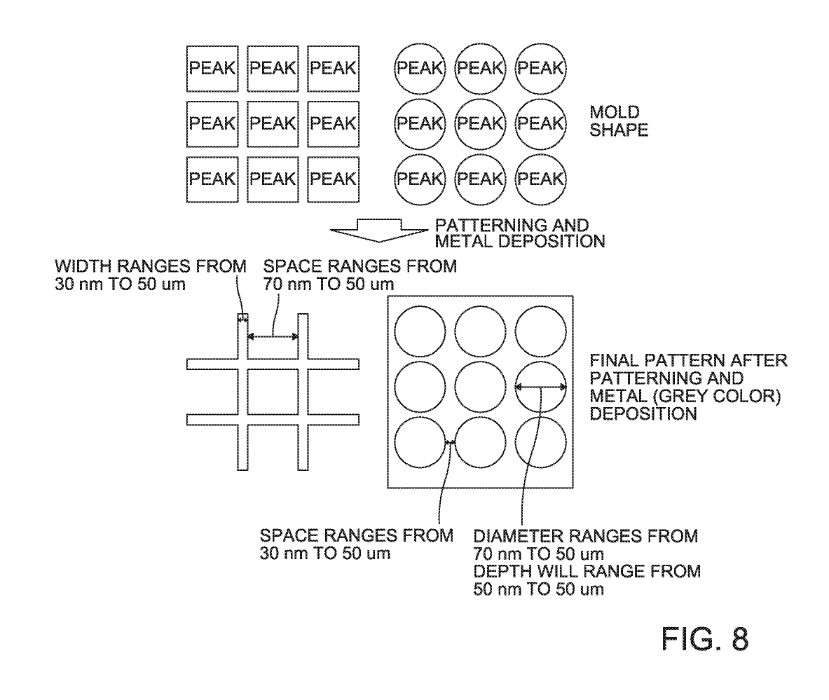

Molds can be formed by any suitable method, such as laser interference lithography. One embodiment using laser interference lithography is depicted in FIG. 1. A He—Cd laser emits light of 325 nm which is reflected by a first mirror through an electronic shutter. The light is then reflected by a second mirror to a beam expander and then to a rotational stage where the light is directed onto a blank used to form the mold (labeled as “sample” in the figure). Another mirror reflects light onto the blank creating an interference pattern. The “blank” is the mold material prior to forming peaks and valleys via, for example, the laser interference lithography method. Utilization of the shutter and rotational stage allows creation of a mold having a series of peaks and valleys as shown in FIG. 2. The mold is then attached to a roll where the mold encircles the roll as depicted in FIG. 2. In some embodiments, an adhesive is used to adhere the mold to the roll. Rolls can be made from any suitable material. These materials include plastics and metal. Some rolls are made from materials comprising polydimethylsiloxane (PDMS) or nickel. While any suitable shape may be used, certain peaks are square, rectangular, circular, or cylindrical in shape, and can be a combination of one of more of these shapes. Exemplary peak shapes are shown in FIG. 8. The peaks in the mold are used to form the holes in the polymer coating. Preferred molds comprise quartz, SiO₂, silicone, or an organic polymer.

### Conductive Film Production

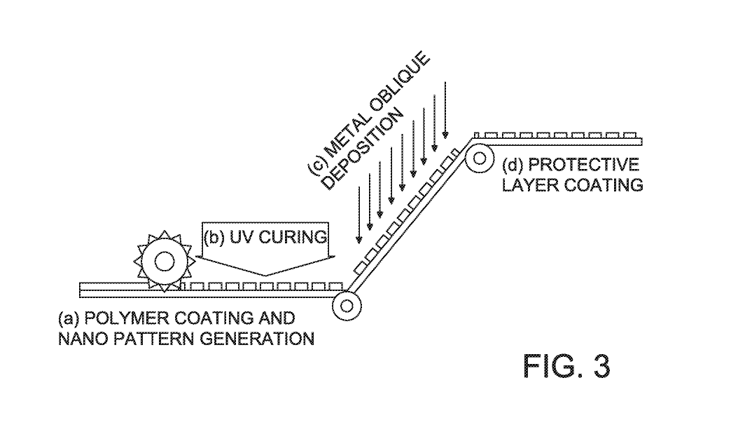

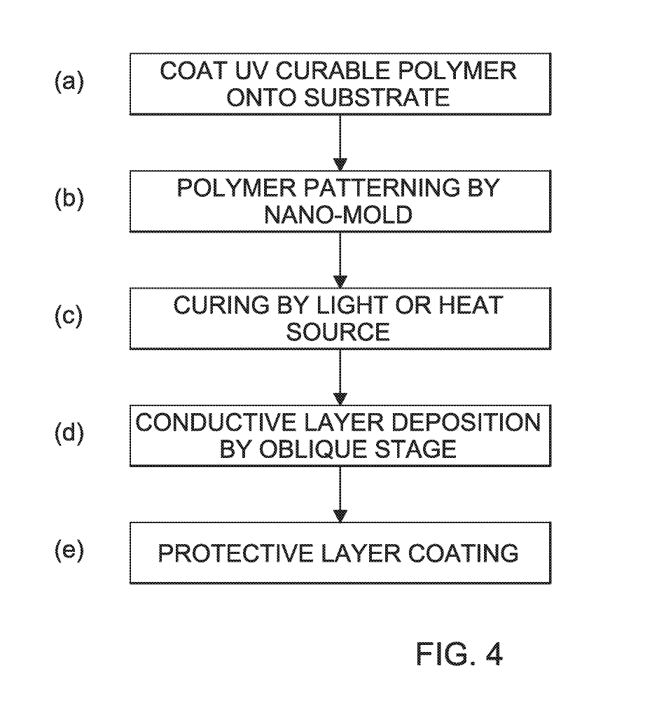

As shown in FIG. 3, a transparent conductive film (e.g., useful as an electrode) can be produced by a method comprising (i) contacting a polymer coating, which resides on a substrate, with a mold, wherein the mold encircles a roller, and wherein the contacting produces a plurality of holes within the polymer coating; the holes occurring at about 100 nm to about 100 μm on the surface of the polymer coating (a frequency of about 50 nm to about 800 nm in certain embodiments); (ii) curing the polymer coating (by exposure to UV radiation, for example) to produce a cured polymer coating; and (iii) depositing a metal layer on the cured polymer coating. The metal layer may be deposited at an oblique angle to the polymer coating surface. Optionally, a protective layer may be added to cover the metal layer.

In some embodiments, the holes have a frequency from about 100 nm to about 100 μm on the surface of the polymer coating, or the frequency may be about 200 nm to about 50 μm, or 300 nm to about 25 μm, or about 400 nm to about 1 μm, or about 500 nm to about 750 nm, or about 600 nm to about 700 nm, or any combination of these values. With respect to circular or square holes, the diameter or width of such holes range from about 70 nm to about 50 μm, including, without limitation, from about 100 nm to about 25 μm, about 200 nm to about 20 μm, about 300 nm to about 10 μm, about 400 nm to about 1 μm or about 500 nm to about 800 nm, or any combination of these values. The holes typically have a depth of from about 50 nm to about 50 μm, about 75 nm to about 25 μm, or about 100 nm to about 10 μm, or about 500 nm to about 1 μm, or any combination of these values. In addition, the shortest distance between the edges or sides of two holes typically ranges from about 30 nm to about 50 μm, including, without limitation, from about 50 nm to about 25 μm, about 100 nm to about 10 μm, about 250 nm to about 1 μm, about 500 nm to about 800 nm, or any combination of these values.

### Substrate

Any suitable substrate that can support the polymer coating may be utilized. The substrate is typically a layer of material on which the polymer coating is deposited and can take different shapes or forms depending on the desired application. Certain substrates are plastic. The thickness of the substrate and the thickness of the polymer coating range from a few microns to a few tens of nanometers in thickness. In some embodiments, the substrate is comprised of one or more of polycarbonate (PC), polyethylene terephthalate (PET), polyethylene naphthalate (PEN), polyethylene (PE) and polyethersolfone (PES). Preferably, the substrate is transparent.

Optionally, the substrate can act as a barrier layer to restrict moisture and oxygen passage through the electrode film. In certain embodiments, barrier materials such as Al₂O₃ or ZrO, ZnO, SiO₂, or SiN can be deposited on plastic substrate.

### Substrate Polymers

### Polycarbonate (PC)

The terms “polycarbonate” or “polycarbonates” as used herein includes copolycarbonates, homopolycarbonates and (co)polyester carbonates. PC polymers are available commercially from SABIC.

The term polycarbonate can be further defined as compositions have repeating structural units of the formula (1):

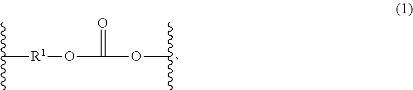

in which at least 60 percent of the total number of R1 groups are aromatic organic radicals and the balance thereof are aliphatic, alicyclic, or aromatic radicals. In a further aspect, each R1 is an aromatic organic radical and, more preferably, a radical of the formula (2):

-A1-Y1-A2- (2),

wherein each of A1 and A2 is a monocyclic divalent aryl radical and Y1 is a bridging radical having one or two atoms that separate A1 from A2. In various aspects, one atom separates A1 from A2. For example, radicals of this type include, but are not limited to, radicals such as —O—, —S—, —S(O)—, —S(O2)-, —C(O)—, methylene, cyclohexyl-methylene, 2-[2.2.1]-bicycloheptylidene, ethylidene, isopropylidene, neopentylidene, cyclohexylidene, cyclopentadecylidene, cyclododecylidene, and adamantylidene. The bridging radical Y1 is preferably a hydrocarbon group or a saturated hydrocarbon group such as methylene, cyclohexylidene, or isopropylidene. Polycarbonate materials include materials disclosed and described in U.S. Pat. No. 7,786,246, which is hereby incorporated by reference in its entirety for the specific purpose of disclosing various polycarbonate compositions and methods for manufacture of the same.

In some embodiments a melt polycarbonate product may be utilized. The melt polycarbonate process is based on continuous reaction of a dihydroxy compound and a carbonate source in a molten stage. The reaction can occur in a series of reactors where the combined effect of catalyst, temperature, vacuum, and agitation allows for monomer reaction and removal of reaction by-products to displace the reaction equilibrium and effect polymer chain growth. A common polycarbonate made in melt polymerization reactions is derived from bisphenol A (BPA) via reaction with diphenyl carbonate (DPC). This reaction can be catalyzed by, for example, tetra methyl ammonium hydroxide (TMAOH) or tetrabutyl phosphonium acetate (TBPA), which can be added in to a monomer mixture prior to being introduced to a first polymerization unit and sodium hydroxide (NaOH), which can be added to the first reactor or upstream of the first reactor and after a monomer mixer.

Generally polycarbonates can have a weight average molecular weight (Mw), of greater than about 5,000 g/mol based on PS standards. In one aspect, the polycarbonates can have an Mw of greater than or equal to about 20,000 g/mol, based on PS standards. In another aspect, the polycarbonates have an Mw based on PS standards of about 20,000 to 100,000 g/mol, including for example 30,000 g/mol, 40,000 g/mol, 50,000 g/mol, 60,000 g/mol, 70,000 g/mol, 80,000 g/mol, or 90,000 g/mol. In still further aspects, the polycarbonates have an Mw based on PS standards of about 22,000 to about 50,000 g/mol. In still further aspects, the polycarbonates have an Mw based on PS standards of about 25,000 to 40,000 g/mol.

### Polyethylene Terephthalate (PET)

Polyethylene terphtalate (PET) is a polyester polymer. As used herein the terms “poly(ethylene terephthalate)” and “PET” include PET homopolymers PET copolymers and PETG. As used herein the term PET copolymer refers to PET that has been modified by up to 10 mole percent with one or more added co-monomers. For example the term PET copolymer includes PET modified with up to 10 mole percent isophthalic acid on a 100 mole percent carboxylic acid basis. In another example the term PET copolymer includes PET modified with up to 10 mole percent 1,4 cyclohexane dimethanol (CHDM) on a 100 mole percent diol basis. As used herein the term PETG refers to PET modified with 10 to 50 percent CHDM on a 100 mole percent diol basis. The term “PCTG” refers to PET modified with 50 to 95 percent CHDM on a 100 mole percent diol basis.

Some PET polymers are of the following formula (3).

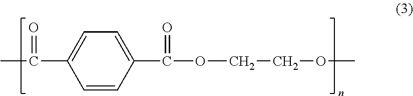

### Polyethylene Naphthalate (PEN)

Polyethylene naphthalate (PEN) is a polyester polymer derived from naphthalene-2,6-dicarboxylate and ethylene glycol. A representative formula (4) is shown below.

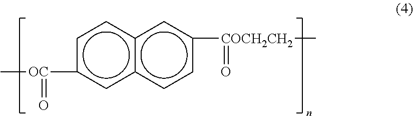

### Polyethylene (PE)

Polyethylene polymer comprises a number of repeat units derived from ethylene —(CH₂CH₂)ₙ—. The polymer is available commercially in a variety of grades including high-density polyethylene (HDPE), low-density polyethylene (LDPE), and linear low-density polyethylene LLDPE.

### Polyethersolfone (PES)

Polyethersulfone polymer may be of the following formulas (5 and 6). PES polymers are available commercially from SABIC.

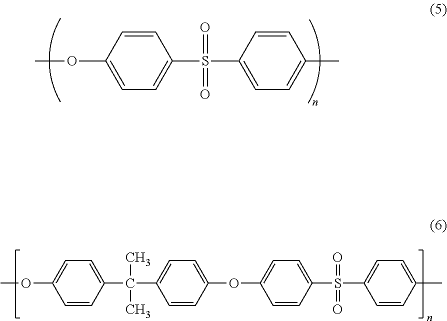

### Polymer Coating for the Substrate

Any suitable polymer may be utilized as the polymer coating. In some embodiments, thickness of the polymer coating ranges from about 50 nm to about 150 μm, or about 75 nm to 125 μm or about 100 nm to about 50 μm, or about 500 nm to about 1 μm, or any combination of these values. In some embodiments, the polymer is a UV curable polymer and the curing of the polymer comprises exposing the polymer to UV radiation. Some preferred polymers include polydimethylsiloxane and acryl based polymers.

Acryl based polymers include derivatives of acrylate monomers in their structure. Suitable monomers include acrylic acid, methyl acrylate, methyl methacryate, ethyl acrylate, 2-Chloroethyl vinyl ether, 2-ethylhexyl acrylate, hydroxyethyl methacrylate, butyl acrylate, and butyl methacrylate.

Polydimethylsiloxane polymers (PDMS) are a commonly used silicone-based organic polymer based on repeating monomer [SiO(CH₃)₂] units. In some embodiments PDMS can be depicted by structure 7.

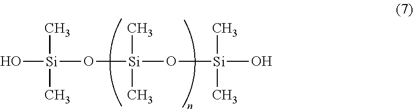

### Conductive Polymer

Any suitable conductive polymer can be used with the instant invention. Such conductive polymers include the following compounds.

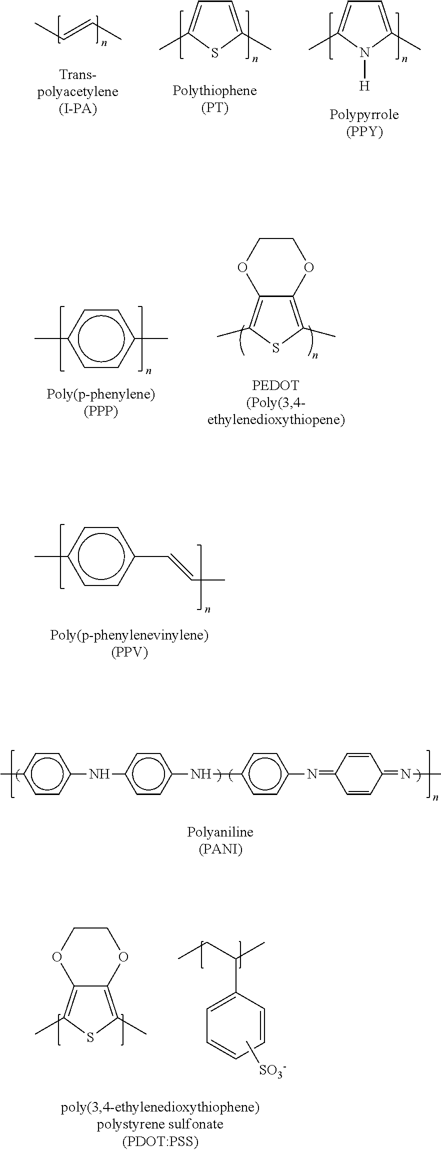

Some OLED electrodes use PEDOT:PSS as the conducting polymer. PEDOT:PSS is transparent polymer mixture of the two ionomers depicted above.

### Metal Coating

The metal coating layer should be electrically conductive. Preferably, the metal coating is transparent. Suitable metals include aluminum, silver, chromium, nickel and platinum. The metal coating layer may be applied by conventional techniques. These techniques include chemical vapor deposition (“CVD”), physical vapor deposition (“PVD”), and atomic layer deposition (“ALD”). The metal coating layer is typically about 10 nm to about 100 nm thick. In certain embodiments, the layer is about 10 nm to about 20 nm thick, about 20 to about 30 nm thick, about 30 nm to about 40 nm thick, about 40 nm to about 50 nm thick, about 50 nm to about 60 nm thick, about 60 nm to about 70 nm thick, about 70 nm to about 80 nm thick, about 80 nm to about 90 nm thick, about 90 nm to about 110 nm thick, or any combination of these values.

In some embodiments, metal deposition is accomplished using oblique angle deposition techniques. Oblique-angle deposition (OAD) technique is based on traditional vapor-deposition processes with a tilted and rotating substrate. The technique allows the growth of thin films on certain portions of the mold. For example, the deposition may be on the “top” surface of the polymer coating between the holes as well as on the polymer coating surface that forms the “sides” or walls of the holes. In certain embodiments, the deposition is preferably on these top and side surfaces as opposed to the surface forming the “bottom” of the hole. In certain embodiments, deposition is performed at an angle of from about 10° to about 80° relative to top surface. See, e.g., FIG. 3. In certain embodiments, the angle is about 10° to about 20°, about 20° to about 30°, about 30° to about 40°, about 40° to about 50°, about 50° to about 60°, about 60° to about 70°, about 70° to about 80°, or any combination of these values.

### Protective Layer

A protective layer may be added to provide protection against abrasion or oxidation of the metal layer. The protective layer typically comprises a plastic which allows the film to remain transparent. Suitable plastics include fluorine based silicones. In certain embodiments, poly(3,4-ethylenedioxythiophene) polystyrene sulfonate (PEDOT:PSS) can be used to coat the electrode film. In some embodiments, the protective layer thickness ranges from about 50 nm to about 150 μm. In certain embodiments, the thickness is about 100 nm to about 110 μm. For example, the thickness of the protective layer may be about 10 nm to about 20 nm, about 20 to about 30 nm, about 30 nm to about 40 nm, about 40 nm to about 50 nm, about 50 nm to about 60 nm, about 60 nm to about 70 nm, about 70 nm to about 80 nm, about 80 nm to about 90 nm, about 90 nm to about 110 nm, or any combination of these values.

In some embodiments, poly(3,4-ethylenedioxythiophene) polystyrene sulfonate (PEDOT:PSS) can be used to coat the electrode film.

### Article Production

Once the transparent conductive film is produced, it can be incorporated into articles by conventional techniques. Suitable articles include screens for tablets, notebooks, monitors, and smart phones. Other applications include OLED (organic light emitting diode) lighting, OPV (organic photovoltaics) and DSSCs (dye-sensitized solar cells. Additional applications are use of the conductive films in cap sensors, wearable devices, printed electronics, automotive electronics. Wearable devices that can utilize the conductive films of the instant invention include those used for electrophysiological sensing such as electrocardiography and electromyography.

### OLED Electrodes

OLEDs (organic light-emitting diodes) typically comprise an organic semiconductor situated between two electrodes. The organic semiconductor emits light when stimulated by an electric current. One or both of the electrodes is typically transparent.

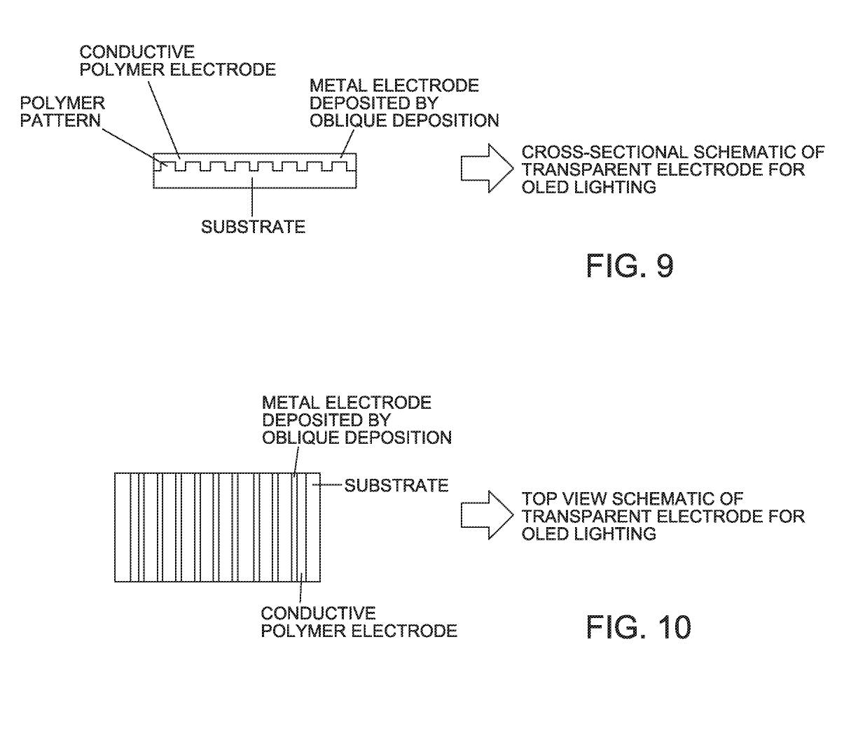

The instant electrodes find applicability to OLED lighting devices. FIG. 9 shows a cross-sectional schematic of a transparent electrode for OLED lighting. Features include a substrate, patterned polymer on the top surface of the substrate, metal electrode deposited by oblique deposition onto the patterned polymer layer and a conductive polymer layer on the top surface of the metal electrode. FIG. 10 presents a top view schematic of a transparent electrode for OLED lighting. Showing the substrate, conductive polymer and metal electrode.

The materials for the OLED electrodes are as described herein. In such OLED electrodes, the height of the patterned polymer ranges from about 20 nm to about 200 nm. Conductive polymer may be coated on the top of the metal electrode. Thickness of the conductive polymer layer ranges from about 50 nm to about 1 μm.

### Examples

The disclosure is illustrated by the following non-limiting examples. Unless otherwise stated to the contrary herein, all test standards are the most recent standard in effect at the time of filling this application.

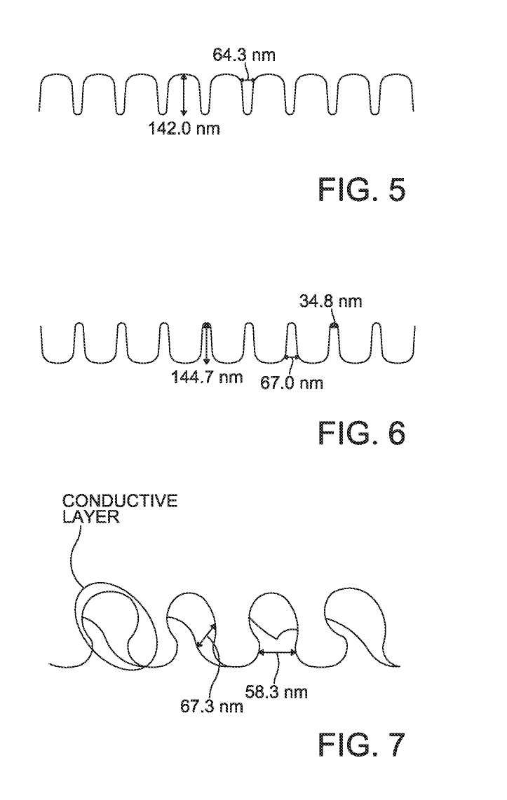

FIG. 5 shows a nano pattern created by techniques known in the art. By using a mold of the instant invention, a pattern was produced in the polymer coating and shown in FIG. 6. Onto this pattern, a conductive layer was obliquely deposited. The transparent electrode film with conductive layer is shown in FIG. 7. It was observed that the conductive layer is only deposited on the top surface of the polymer coating between the holes and the polymer coating surface that forms the sides of walls of the hole, as opposed to being deposited on the bottom surface of the hole. As used herein, the term “bottom” refers to the surface of a hole remote from the “top”. The “top” is the polymer coating surface between the holes. “Sides” refers to the surfaces of the hole that run from the bottom to the top of the hole to form the sides or walls of the hole. As a result of the conductive layer residing on the “top” and “side” portions, one does not need to perform an etching process to remove any conductive layer at the bottom portion of the hole as is required by conventional techniques. Confirmation that the conductive layer was not deposited on the bottom portion/surface of the hole was verified by measuring the transmittance at various wavelengths through the conductive film. It was shown that samples having obliquely deposited coatings of various thicknesses had high transmittance (Table 1). The best performance in Table 1 of a sample film's transmittance was above 90%, while transmittance of films utilizing conventional silver nano wire or silver nano particles was about 84% to about 87% of transmittance.

In Table 1, transmittance of films comprising PET substrate, acryl based polymer, and aluminum metal were tested at various wavelengths where the conductive layer was obliquely deposited at various thicknesses. Transmittance (Tr) was measured at a 50 degree angle using a spectrophotometer.

TABLE 1

| Thickness | Wavelength | 50 degree |
|---|---|---|
| (nm) | (nm) | Tr |
| 20 | 633 | 93 |
| | 532 | 90 |
| | 473 | 91.5 |
| 25 | 633 | 89 |
| | 532 | 90 |
| | 473 | 91.5 |
| 30 | 633 | 88 |
| | 532 | 88.5 |
| | 473 | 85.5 |

As an additional example, an OLED electrode is produced as shown in FIGS. 9 and 10. A patterned polymer layer is produced on the top surface of a substrate. A metal electrode is then deposited by oblique deposition onto the patterned polymer layer. Next, a conductive polymer layer is deposited on the top surface of the metal electrode.

### Aspects

The present disclosure comprises at least the following aspects.

Aspect 1. A method of producing a transparent electrode film comprising:
contacting a polymer coating, which resides on a substrate, with a mold, wherein the mold encircles a roller, and wherein the contacting produces a plurality of holes within the polymer coating; the holes occurring at a frequency period of 100 nm to about 100 μm;
curing the polymer coating to produce a cured polymer coating; and
depositing a metal layer on the cured polymer coating.

Aspect 2. The method of Aspect 1, wherein the mold is formed by laser interference lithography.

Aspect 3. The method of Aspect 1 or Aspect 2, further comprising applying a protective layer onto the metal layer.

Aspect 4. The method of anyone of Aspects 1-3, wherein the metal layer is electrically conductive.

Aspect 5. The method of Aspect 4, wherein the metal comprises at least one of aluminum, silver, chromium, nickel or platinum.

Aspect 6. The method of any one of Aspects 1-5, wherein the metal is deposited by oblique angle deposition.

Aspect 7. The method of Aspect 6, wherein the oblique angle deposition utilizes an angle of about 10° to about 80°.

Aspect 8. The method of any one of Aspects 1-7, wherein the metal layer is from about 10 nm to 100 nm thick.

Aspect 9. The method of any one of Aspects 1-8, wherein the protective layer comprises plastic.

Aspect 10. The method of any one of Aspects 1-9, wherein the polymer is a UV curable polymer and the curing of the polymer comprises exposing the polymer to UV radiation.

Aspect 11. The method of Aspect 10, wherein the polymer comprises polydimethylsiloxane or acryl based polymer.

Aspect 12. The method of any one of Aspects 1-9, wherein the curing of the polymer comprises exposing the polymer to a temperature between about 25° C. and about 150° C.

Aspect 13. The method of Aspect 12, wherein the substrate comprises polyethylene terephthalate, polycarbonate, or polyethylene naphthalate.

Aspect 14. The method of any one of Aspects 1-13, wherein the holes have a frequency is from 100 nm to 1 μm on the film.

Aspect 15. The method of any one of Aspects 1-14, wherein the holes have a diameter of from 50 nm to 1 μm.

Aspect 16. The method of any one of Aspects 1-15, wherein the holes have a depth of from 10 nm to 100 nm.

Aspect 17. The method of any one of Aspects 1-16, wherein the laser interference lithography contacts light from a laser onto a mold substrate utilizing a shutter to regulate the light.

Aspect 18. The method of any one of Aspects 1-17, wherein the mold comprises quartz, SiO₂, silicone, or an organic polymer.

Aspect 19. The method of any one of Aspects 1-18, wherein the mold comprises polydimethylsiloxane.

Aspect 20. An OLED electrode comprising (i) substrate, (ii) patterned polymer layer on the substrate, (iii) metal electrode deposited onto the patterned polymer, and (iv) conductive polymer deposited on the metal electrode.

Aspect 21. The OLED electrode of Aspect 20, wherein the substrate comprises one or more of polyethylene terephthalate, polyethylene naphthalate, and polyethersolfone.

Aspect 22. The OLED electrode of Aspect 20 or 21, wherein the patterned polymer comprises polymer comprising acrylate monomers or silicone-based organic polymer.

Aspect 23. The OLED electrode of any one of Aspects 20-22, wherein the conductive polymer comprises poly(3,4-ethylenedioxythiophene) polystyrene sulfonate.

Aspect 24. The OLED electrode of any one of Aspects 20-23 where the patterned polymer layer comprises a plurality of holes within the polymer layer; the holes occurring at a frequency period of 100 nm to about 100 μm.

Aspect 25. The OLED electrode of Aspect 24, wherein the holes have a diameter of from 50 nm to 1 μm.

Aspect 26. The OLED electrode of any one of claims 20-25, wherein the holes have a depth of from 10 nm to 100 nm.

### Definitions

It is to be understood that the terminology used herein is for the purpose of describing particular aspects only and is not intended to be limiting. As used in the specification and in the claims, the term “comprising” can include the embodiments “consisting of” and “consisting essentially of” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one particular value to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated ±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Disclosed are the components to be used to prepare the compositions of the disclosure as hole as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

As used herein, the term “transparent” means that the level of transmittance for a disclosed composition is greater than 50%. In some embodiments, the transmittance can be at least 60%, 70%, 80%, 85%, 90%, or 95%, or any range of transmittance values derived from the above exemplified values. In the definition of “transparent”, the term “transmittance” refers to the amount of incident light that passes through a sample measured by a spectrophotometer. In some embodiments, transparency can measured in accordance with ASTM D1003 at a thickness of 1 millimeter.

Oblique-angle deposition (“OAD”) is a vapor phase deposition couples a conventional vapor phase deposition process with a tilted and rotating substrate. Deposition at an oblique angle to the surface of a substrate is utilized in forming a layer on the substrate.

An “oblique angle” is an angle that not a right angle or a multiple of a right angles. Some oblique angles are acute and obtuse angles.

Laser interference lithography (“LIL”) is a technique for producing nanometer-scale, periodically patterned structures. Patterns are recorded in a light-sensitive medium responding to the interference of two or more coherent beams of light. Such techniques are well known in the art.

The term “mold” means an article having a patterned surface. The mold may encircle a roller which can be used to contact the polymer coating of a substrate and produce a plurality of holes within the polymer coating.

The phrase “electrically conductive” means that the material permits the flow of electrical current through the material.

A “frequency” or “frequency period” refers to a periodic appearance of a well or hole or valley within the polymer coating (i.e., the distance between the center of one hole and that of an adjacent hole). Frequency is typically expressed in a distance unit (nanometers (nm), for example).

Holes (sometimes referred to as “wells”) are a depression having a depth and width within the polymer coating. Holes can vary in size and shape as needed for the particular application.

1. A method of producing a transparent electrode film comprising:
contacting a polymer coating, which resides on a substrate, with a mold, wherein the mold encircles a roller, and wherein the contacting produces a plurality of holes within the polymer coating, the holes occurring at a frequency period of 100 nanometers (nm) to about 100 micrometers (μm);
curing the polymer coating to produce a cured polymer coating; and
depositing a metal layer on the cured polymer coating.

2. The method of claim 1, wherein the mold is formed by laser interference lithography.

3. The method of claim 1, further comprising applying a protective layer onto the metal layer.

4. The method of claim 1, wherein the metal layer is electrically conductive.

5. The method of claim 4, wherein the metal layer comprises at least one of aluminum, silver, chromium, nickel or platinum.

6. The method of claim 1, wherein the metal layer is deposited by oblique angle deposition.

7. The method of claim 6, wherein the oblique angle deposition utilizes an angle of about 10° to about 80°.

8. The method of claim 1, wherein the metal layer is from about 10 nm to 100 nm thick.

9. The method of claim 1, wherein the protective layer comprises plastic.

10. The method of claim 1, wherein the polymer coating comprises an ultra violet (UV) curable polymer and the curing of the polymer coating comprises exposing the polymer coating to UV radiation.

11. The method of claim 10, wherein the polymer coating comprises polydimethylsiloxane or acryl based polymer.

12. The method of claim 1, wherein the curing of the polymer coating comprises exposing the polymer coating to a temperature between about 25° C. and about 150° C.

13. The method of claim 12, wherein the substrate comprises polyethylene terephthalate, polycarbonate, or polyethylene naphthalate.

14. The method of claim 1, wherein the holes have a frequency period from 100 nm to 1 μm on the film.

15. An OLED electrode comprising: (i) a substrate; (ii) a patterned polymer layer disposed on the substrate; (iii) a metal electrode disposed on the patterned polymer; and (iv) a conductive polymer disposed on the metal electrode.

16. The OLED electrode of claim 15, wherein the substrate comprises one or more of polyethylene terephthalate, polyethylene naphthalate, and polyethersolfone.

17. The OLED electrode of claim 15, wherein the patterned polymer layer comprises acrylate monomers or a silicone-based organic polymer.

18. The OLED electrode of claim 15, wherein the conductive polymer comprises poly(3,4-ethylenedioxythiophene) polystyrene sulfonate.

19. The OLED electrode of claim 15, where the patterned polymer layer comprises a plurality of holes within the polymer layer, the holes occurring at a frequency period of 100 nm to about 100 μm.

20. The OLED electrode of claim 19, wherein the holes have a diameter of from 50 nm to 1 μm and a depth of from 10 nm to 100 nm
